(19) United States
(12) Patent Application Publication
(10) Pub. No.: US 2009/0194505 A1
(43) Pub. Date: Aug. 6, 2009

(54) VACUUM COATING TECHNIQUES

(75) Inventor: W. Dennis Slafer, Arlington, MA (US)

Correspondence Address: MCDERMOTT WILL & EMERY LLP, 28 STATE STREET, BOSTON, MA, 02109-1775, US

(73) Assignee: MICROCONTINUUM, INC., Cambridge, MA (US)

(21) Appl. No.: 12/359,559

(22) Filed: Jan. 26, 2009

Related U.S. Application Data
(60) Provisional application No. 61/023,134, filed on Jan. 24, 2008.

(51) Int. Cl. B44C 1/22; C23C 16/54; C23F 1/08

(52) U.S. Cl. 216/59; 118/718; 204/298.02; 156/345.54; 216/67

(57) ABSTRACT

Techniques are described for improving the quality and yield of vacuum-processed substrates. A system can include a tape-like substrate that is supplied by unwind spool to a web guide, tension control roller, and additional idler rolls. The substrate can then enter a coating zone, following an essentially spiral pathway and traversing the coating source a number of times before exiting the coating zone and rewinding on spool. The effect of multiple passes through various flux areas of source is to smooth and average out the coating thickness non-uniformities resulting from a non-uniform flux. Related methods are described. Embodiments can be particularly well suited for the manufacture of data tapes including, but not limited to, metal evaporated magnetic, magneto-optical, phase change optical, and preformatted, or thin-film electronics, sensors, RFID tags, and solar films, to name a few examples.

### RELATED APPLICATION

This application claims the benefit of U.S. Provisional Patent Application No. 61/023,134 filed 24 Jan. 2008 and entitled “Improved Vacuum Coating Method,” the entire contents of which are incorporated herein by reference.

### BACKGROUND

Vacuum roll coating has long been used to deposit single and multiple layers of metallic and non-metallic materials on flexible substrates. One particular advantage of vacuum roll coating is in its ability to coat large substrate areas, with the largest vacuum coating machines being capable of handling rolls of substrate exceeding 10 feet in width and coating speeds in excess of several thousand feet per minute (41st Annual Technical Conference Proceedings, Society of Vacuum Coaters, Boston Mass. 18 Apr., 1998, pg. 26 ff).

Vacuum roll coaters utilize one or more techniques to deposit the desired film layers, common techniques including thermal evaporation, electron beam (e-beam) evaporation, sputtering, chemical vapor deposition (CVD), polymer multilayer (PML), etc. Some deposition processes are characterized by relatively high material deposition rates but do not necessarily produce a high degree of deposition uniformity.

Deposition quality in roll-to-roll vacuum coating is often stated in terms of transverse (cross-web) and longitudinal (machine direction) uniformity, corresponding to thickness or compositional variations across the width and along the length of the roll, respectively. Cross-web and machine direction variations can arise from several sources, including non-uniform spatial and temporal distributions of the flux from the material source.

Other types of roll-to-roll vacuum process include subtractive processes, such as plasma etching or ablation, etc., which are used to remove material (polymers, metals, oxides and other inorganic layers, etc.). These vacuum processes are also subject to variations in process uniformity, and in the discussions below relating to deposition processes, it should be noted that such considerations apply to plasma etch and related processes as well.

There are a number of techniques known to the art to control and minimize such fluctuations, including use of sensors to control material deposition or removal through a feedback means (crystal monitors, reflectometers, etc.), which typically affect temporal variations from the source, and shutters or e-beam scanning, which typically affects the spatial material distribution. FIGS. 1-3 depict representative system of the prior art and illustrate how non-uniform coatings result from non-uniform source distributions.

In a typical configuration, shown both in FIG. 1a in side view, and FIG. 1b in normal perspective view, the substrate 1 to be coated, herein also referred to by convention as the web, is feed from a supply spool 2, and after passing over additional roll 3 to control tension and positioning, etc., the substrate enters coating zone 5, which includes source 6 from which material for the first layer 7 is deposited, and coating barriers 8 to minimize overcoating of excess material from the source. Additional materials may be deposited at sequentially located coating zones (not shown), after the last of which the coated substrate, after passing over additional tensioning and positioning roll 4, is taken up on re-wind spool 12. In this known art, the substrate traverses the coating zone in an essentially linear direction, and the web may be either a free span, i.e., unsupported on the back side, or in contact with a backing plate 13 or roll which is typically used to cause the web to lie flat and/or to remove excess heat from the deposition process. In the latter case, the backing plate or roll can optionally be cooled. It should be noted that similar designs can be applied to vacuum removal processes, such as plasma etching.

In the figures of this disclosure, motors, speed control elements, tension controls, web guides and the like are not shown in the figures of this disclosure for clarity, but such control systems are well known to the art (D. R. Roisum, The Mechanics of Rollers, TAPPI Press, Atlanta, 1996).

Now referring to FIG. 2, a general schematic of practice common to the art is given of the cross-section of a substrate during the vacuum deposition process, as viewed in the machine direction. This diagram shows one example in which a non-uniform deposition of material 19 arises from a non-uniform flux distribution 17 from the source, where crucible 15 filled with material 16 is evaporated (for example, by means of resistively heating crucible, not shown). The flux, typically described as the mass or thickness of material being evaporated per unit time, is shown graphically as distribution 17, where the highest rate of evaporation is represented by the longest arrow (at the center in this example). Material 19 generally condenses on substrate 18 in proportion to the flux distribution, and is thus distributed as material layer 19, with the thickness being approximately proportional to flux 17. In the case of material removal (plasma etching or ablation), the material source may be replaced by a removal source, and similar uniformity issue may arise.

FIG. 3 represents the normal-incidence view of a non-uniform coating similar to that of FIG. 2 that can result from a non-uniform flux distribution. Here, unwind spool 24 supplies substrate 25 to coating zone 26 over guide/tension/idler rollers (represented here by 27). Material 30 is evaporated from crucible 28, with deposition shields 29 minimizing stray coating. The coated substrate 31 travels over additional guide/tension/idler rollers (represented here by 32) and is rewound on take-up spool 34. The horizontal dotted lines 35 indicate hypothetical slitting locations if this substrate were ultimately to be made into a tape product. Variations in coating thickness 36 are the result of the non-uniform flux from crucible, as shown previously (FIG. 2).

It is typically more difficult to maintain an extremely high degree of uniformity in the cross-web direction than the machine direction, particularly with high deposition rate e-beam and thermal evaporation processes. Contributing factors include non-uniform heating, depletion of the source material during the deposition process, material buildup at the source, (or non-uniform plasma fields in the case of plasma etching), etc. Uniformity can decrease as the deposition material is depleted until the coating process must stop to refill the material reservoirs, although in larger systems the material is replenished continuously, for example by means of wire or screw fed devices. For precision coatings requiring very tight thickness tolerances, the cross-web uniformity achievable by high rate thermal or e-beam deposition or plasma etch processes is often unacceptable.

Following vacuum processing (deposition or removal), it is common to slit the processed material into narrower widths, such as in the case of tape-like materials. The slitting process typically uses a mechanical means to effect the slitting, such as a knife box or other shearing device, and this operation can be a source of problems for the coated substrate. Slitting can result in disruption or delamination of the coating at the slit edges, with the concomitant generation of coating and substrate particles. The particulates thus generated not only contaminate the slit rolls, but they also can be incorporated into the spools under tension during rewind, which can irreversibly damage the rolls, a particular problem in the case of sensitive coatings or substrates.

It is also common to coat both the front and back surfaces. This requires either a second pass through the coating machine or incorporation of a tandem coating/etch station and related web-handling equipment, both of which can add to the cost of process and/or equipment. Thus, improvements remedying such disadvantage are desired.

### SUMMARY

Aspects and embodiments of the present disclosure can substantially eliminate the shortcomings and disadvantages of the prior art noted above, by providing for coating substrates having improved uniformity, edge quality, cleanliness, and higher throughput. The present disclosure provides techniques for improving the quality and yield of vacuum-processed substrates. Embodiments of such techniques (systems and/or methods) can be particularly well suited for the manufacture of data tapes including, but not limited to, metal evaporated magnetic, magneto-optical, phase change optical, and preformatted, or thin-film electronics, sensors, RFID tags, solar films, to name but a few examples.

An aspect of the present disclosure is directed to roll-to-roll systems for providing uniformity of vacuum coated flexible substrates. An embodiment of such a system can generally include: (a) a vacuum system having a source from which a flux of material can be emitted through an area; (b) a means for continuous transport of a substrate through the area of the flux of material (e.g., such as a roll-to-roll system); and (c) a substrate path that includes multiple sequential transits through successive areas of the flux of material emitted from the source.

A further aspect is directed to roll-to-roll methods for improving the uniformity of vacuum etched and/or vacuum coated flexible substrates. An embodiment of such a method can generally include: (a) providing a vacuum system having a material removal zone in which material can be removed from the substrate; (b) continuously transporting a substrate through the material removal zone; and (c) providing a substrate path for the substrate that includes multiple sequential transits through successive areas of the material removal zone.

While aspects of the present disclosure are described herein in connection with certain embodiments, it is noted that variations can be made by one with skill in the applicable arts within the spirit of the present disclosure and the scope of the appended claims.

### BRIEF DESCRIPTION OF THE DRAWINGS

Various aspects of the disclosure may be more fully understood from the following description when read together with the accompanying drawings, which are to be regarded as illustrative in nature, and not as limiting. The drawings are not necessarily to scale, emphasis instead being placed on the principles of the disclosure. In the drawings:

FIGS. 1A-1B depict schematic drawings of the simplified coating path of the one example of a prior art system, from the side view and from a normal incidence view;

FIG. 2 depicts a schematic of a prior art system illustrating the effects of non-uniform source distributions on the coating uniformity as viewed from the direction of substrate motion;

FIG. 3 depicts a schematic of a prior art system illustrating the effects of non-uniform source distributions on the substrate as viewed normal to the plane of the substrate at the deposition zone;

FIG. 4 includes FIGS. 4A-4F, which depict schematic drawings of embodiments of the present disclosure, utilizing a tape path through a vacuum deposition zone;

FIG. 5 depicts a schematic representation of the effects of multiple passes through the coating zone by the method/system of FIG. 4;

FIG. 6 depicts another embodiment of FIG. 4 in which individual idler rolls are used to guide the tape;

FIG. 7 depicts a schematic drawing for one embodiment of the present process whereby unwanted backside coating can be avoided; and

FIG. 8 depicts a schematic drawing for one embodiment of the present process for single-pass dual-sided coating.

It should be understood by one skilled in the art that the embodiments depicted in the drawings are illustrative and variations of those shown as well as other embodiments described herein may be envisioned and practiced within the scope of the disclosure.

### DETAILED DESCRIPTION

The following description refers to several possible embodiments of the disclosure and it is understood that the variations of the embodiments described herein may be envisioned by one skilled in the art, and such variations are intended to fall within the scope of the disclosure and therefore the disclosure and methods are not limited to the following embodiments.

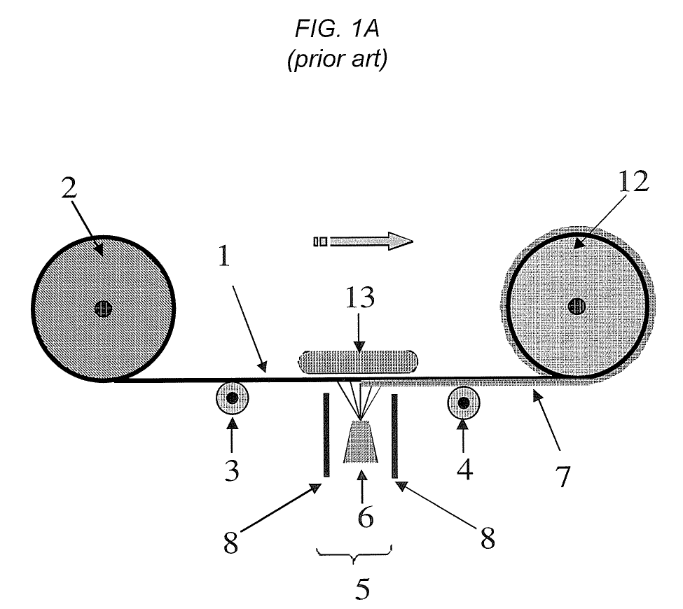

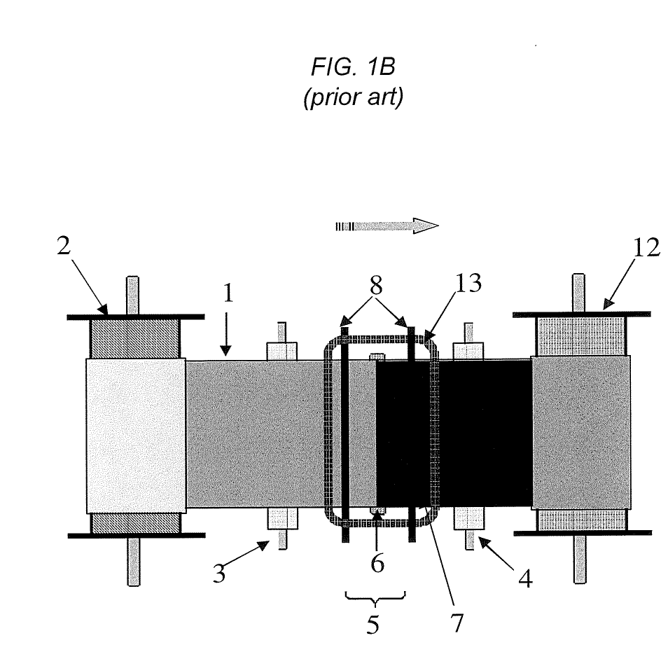

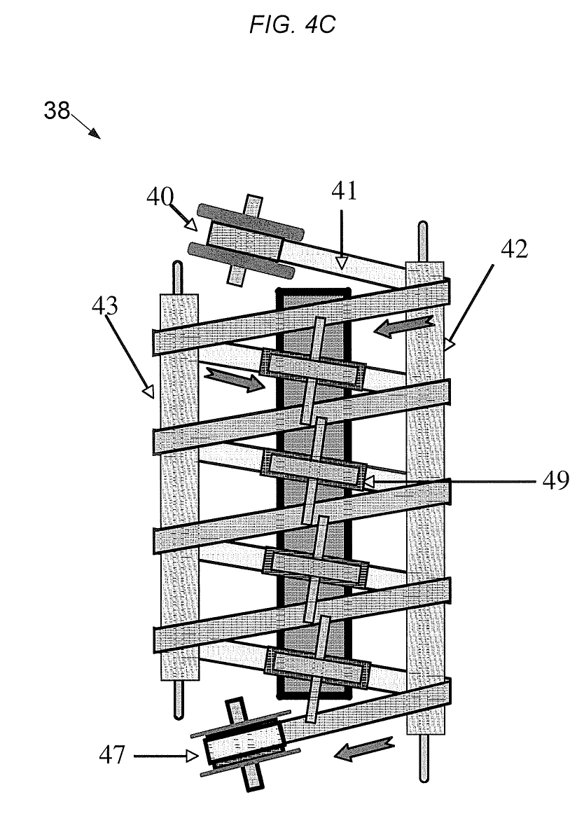

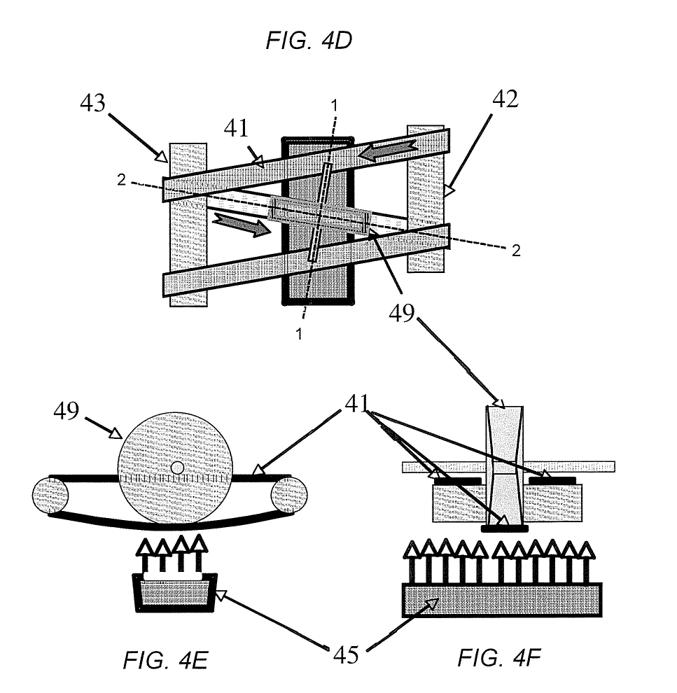

As described previously, FIGS. 1-3 depict representative systems of the prior art and illustrate how non-uniform coatings result from non-uniform source distributions. The subsequent description of FIGS. 4-8 illustrate how embodiments of the present disclosure, which utilize a path allowing multiple passes through a source, can provide for improving the uniformity of a coating.

FIG. 4 includes FIGS. 4A-4F, which depict schematic drawings of embodiments of the present disclosure, utilizing a tape path through a vacuum deposition zone.

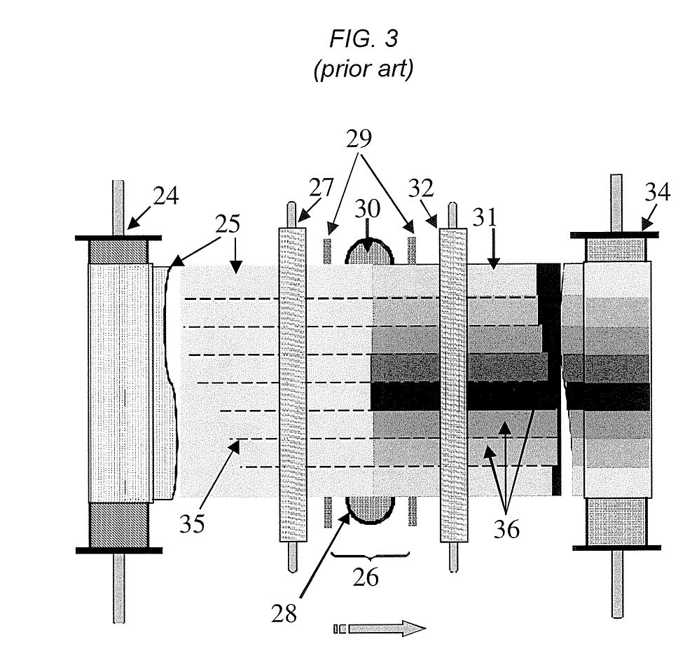

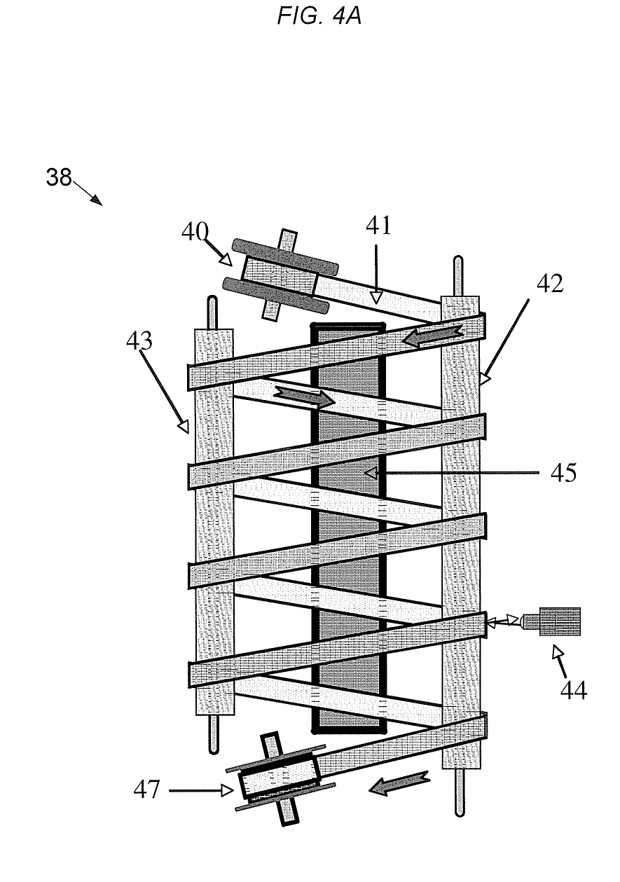

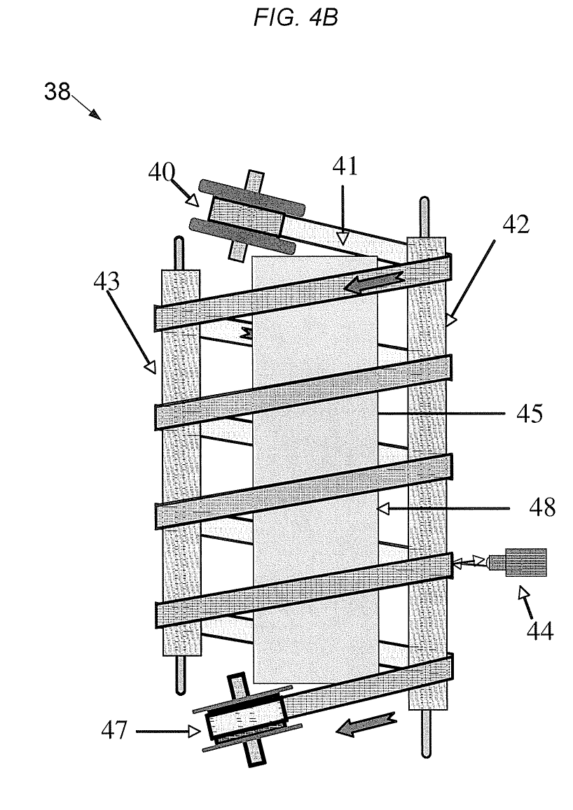

FIG. 4A shows a schematic diagram of one embodiment 38 of the present disclosure in which a tape-like substrate 41 (e.g., a polyethylene terephthalate, PET, or -naphthalate, PEN, or polyimide film or the like) is supplied by unwind spool 40 to a web guide, tension control roller, and additional idler rolls (not shown for clarity), over roll 42, then to roll 43, and then enters coating zone of deposition source material 45, then to roll 42 and back to 43, etc. following an essentially spiral pathway and traversing the coating source 45 a number of times before exiting the coating zone and rewinding on spool 47. The effect of multiple passes through various parts of source 45 is to smooth or ‘average out’ the coating thickness non-uniformities resulting from a non-uniform flux (as, for example, shown by the prior art depiction in FIG. 3). It should be noted that in FIG. 4, the wraps of tape around rolls 42 and 43 are widely separated for purposes of illustration only, and would be close together in an actual coating configuration. It will be noted that a line speed increase will be in proportion to the tape width decrease will maintain an equivalent deposit thickness and throughput for the tape relative to a conventional (full width) coating configuration. Since embodiments of the present disclosure offer increased immunity to source variations resulting from higher flux rates, further speed increases are also possible.

In order to monitor the in situ deposition process, one or more sensors (44) may be disposed at various points of the substrate path. These can be, e.g., one or more reflectometers, fiber-optic sensors (e.g., single or bundled optical fibers configured and arranged to receive light of a desired wavelength or spectrum), cameras, relay mirrors, laser beams, etc. Multi-element sensors, known to the art, can be used to profile the deposit along the width of the substrate and one or more points, for example after each deposition pass. These may be conveniently positioned as desired, e.g., outside or away from the deposition area to prevent inadvertent coating of the measurement system.

In an exemplary embodiment, multiple material deposition and plasma etching steps can be combined in series, such as a first plasma step to clean the substrate and/or to promote adhesion (for example, using an oxygen-argon plasma), followed by a deposition step. In another example, such as in continuous forming of patterns in thin-film layers, an etch step may be required to remove polymer residue (“scum layer”) prior to material deposition.

Examples of suitable deposition and etching techniques/systems are related components/processes, and also further descriptions of suitable means for continuous transport of a substrate and equivalent apparatus/systems (e.g., roll-to-roll techniques), are described in the following of Applicant's co-owned applications: (MCMK-7CP) U.S. patent application Ser. No. 12/358,964 filed 23 Jan. 2009 and entitled “Roll-to-Roll Patterning of Transparent and Metallic Conductors,” which is a continuation-in-part of (MCMK-7) U.S. patent application Ser. No. 11/471,223 filed 20 Jun. 2006 and entitled “Systems and Methods for Roll-to-Roll Patterning,” which claims the benefit of U.S. Provisional Patent Application No. 60/692,078 filed 20 Jun. 2005; (MCMK-4) U.S. patent application Ser. No. 10/588,098 having a § 371(c) filing date of 18 Dec. 2006 and entitled “Apparatus and Method for Manufacturing Preformatted Linear Optical Storage Medium,” which is a national phase application of International Patent Application No. PCT/US05/01856 filed 21 Jan. 2005, which claims the benefit of U.S. Provisional Patent Application No. 60/537,847 filed 21 Jan. 2004 and U.S. Provisional Patent Application No. 60/538,120 filed 21 Jan. 2004; (MCMK-5CP) U.S. patent application Ser. No. 11/509,288 filed 24 Aug. 2006 and entitled “Replication Tools and Related Fabrication Methods and Apparatus,” which (i) claims the benefit of (MCMK-10PR) U.S. Provisional Patent Application No. 60/777,138 filed 27 Feb. 2006 and (ii) is a continuation-in-part of (MCMK-5) U.S. patent application Ser. No. 11/337,013 filed 20 Jan. 2006 and entitled “Replication Tools and Related Fabrication Methods and Apparatus,” which claims the benefit of U.S. Provisional Patent Application No. 60/645,714 filed 21 Jan. 2005; (MCMK-9) U.S. patent application Ser. No. 11/711,928 filed 27 Feb. 2007 and entitled “Formation of Pattern Replicating Tools,” which claims the benefit of U.S. Provisional Patent Application No. 60/777,203 filed 27 Feb. 2007; (MCMK-11) U.S. patent application Ser. No. 11/830,718 filed 30 Jul. 2007 and entitled “Addressable Flexible Patterns,” which claims the benefit of U.S. Provisional Patent Application No. 60/834,105 filed 28 Jul. 2006; the entire contents of all of which applications are incorporated herein by reference.

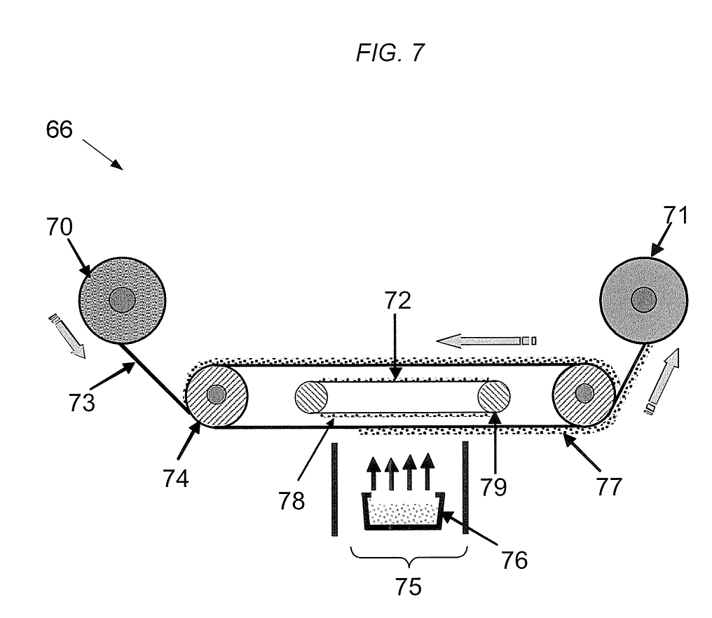

FIG. 4B depicts a variation of the configuration of FIG. 4A, in which element 48 is added as a means (shielding material or mechanism) to prevent excess material from depositing on the backside of the substrate by intercepting excess material from the source. Element 48 can be a static material (plastic or metal film) or a dynamic mechanism (a continuous belt or unwind/rewind transport mechanism the collects excess material for later disposal. The dynamic mechanism may be particularly useful in cases where large amounts of material are deposited (thick coatings and/or long runs) and prevents substantial buildup of excess material on static surfaces that might flake off and contaminate the film or interfere with the coating process. This is also discussed with additional detail in the description of FIG. 7 herein.

In order to reduce the heat load from the deposition process, rollers 42/43 in FIGS. 4A-4B can also be cooled, by circulation of coolant, etc. The higher linear substrate speed and lower deposition rate per pass, in combination with the 180 degree wrap angle of [optionally-chilled] rolls 42/43 between coating passes, will act to reduce the thermal load on the tape from the deposition process.

Additional material support and cooling may be provided through the use of individual support rolls (49) located in the deposition (removal) areas, e.g., as shown in FIG. 4C and in detail in FIGS. 4D-4F, which shows various views of this configuration. FIG. 4E depicts a sectional view of FIG. 4D taken along cutting plane 1-1. FIG. 4F depicts a sectional view of FIG. 4D taken along cutting plane 2-2.

Backing rolls 49 can be designed to be approximately the width of the substrate in order to avoid material buildup on any exposed area of the rolls. The contact faces may be crowned to assist in substrate tracking and the side faces of the rollers can also be recessed or concave for the same reasons. The use of shielding, similar to that shown in FIG. 4B, may also be used.

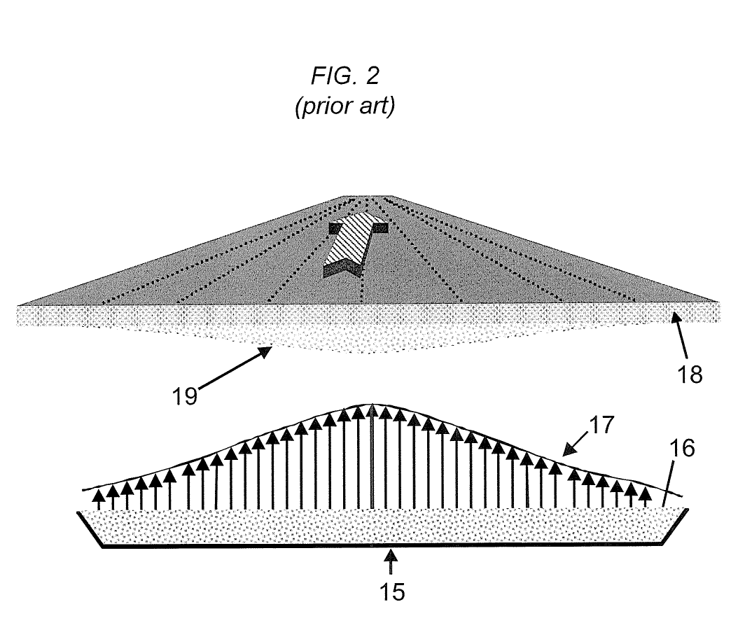

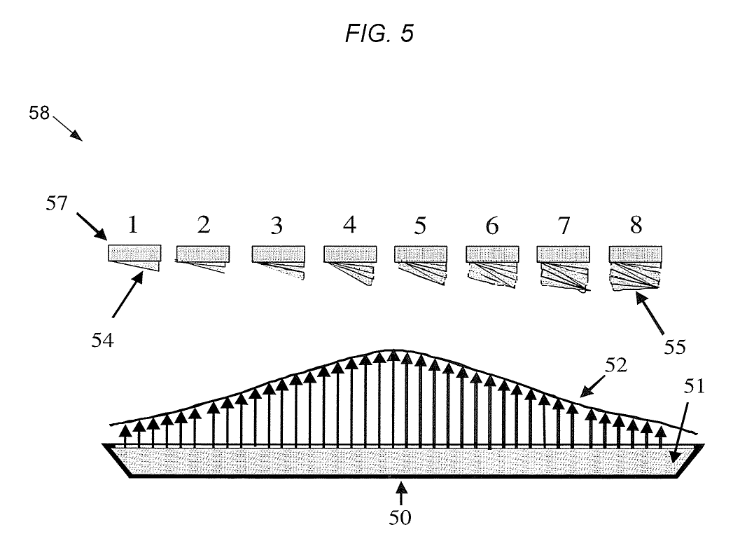

FIG. 5. depicts a schematic representation 58 of the effects of multiple passes through the coating zone by the method/system of FIG. 4. A narrow width substrate, denoted by 57, is depicted in FIG. 5. Following the tape path shown in FIG. 4A, tape substrate 57 in this example makes 8 consecutive traverses through coating zone 50, having material flux emanating from crucible 51 (with the source also having the same non-uniform flux distribution 52 as FIG. 2), where the successive passes of substrate 57 are denoted by positions 1 through 8 (note: the upper traverses of the complete tape path have been eliminated for clarity). The coating layer build-up 54 through 55 is exaggerated to illustrate the smoothing effect. The multiple-pass smoothing effect may be compared to the coating material from the prior art model source distribution shown in FIG. 2, where no multiple-pass smoothing has taken place, after slitting.

It can be appreciated from this illustration that improvement in uniformity may be achieved from most source configurations, since the smoothing effect is based on the width of the substrate being small compared to the width of the source, and multiple passes sample many sections of the material source distribution.

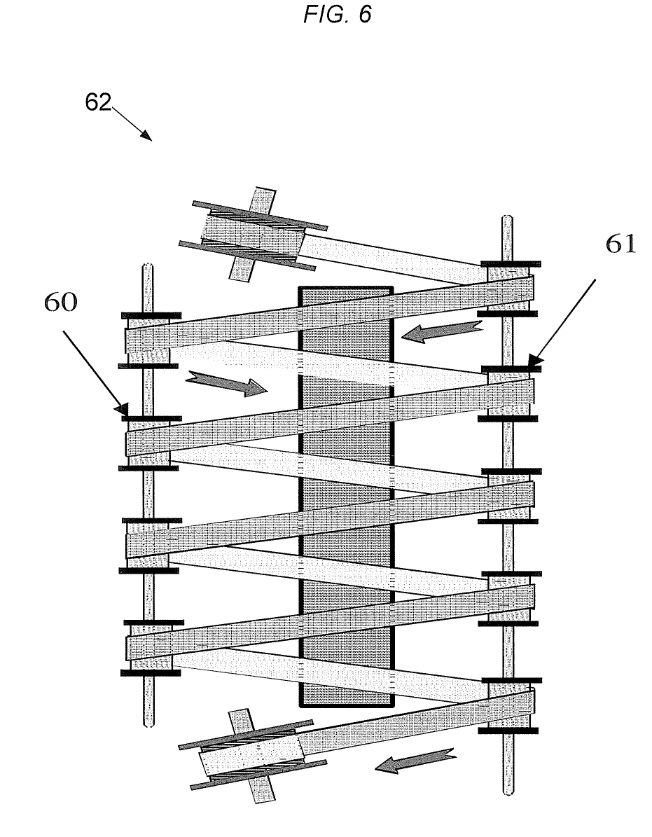

FIG. 6 depicts a further embodiment 62 in which the single rollers 42 and 43 of FIG. 4 have been replaced by multiple individual guide rollers 60 and 61 in order to more precisely guide the tape. This can also be achieved by cutting guide track grooves into rollers 42 and 43. Again, in actual operation, the individual wraps would be close together for maximum uniformity and yield. This can also be combined with the use of shielding and/or backing rolls as discussed above.

It may be seen from the figures that in some cases it is possible for the material to be deposited on the back side of the substrate during the traverse of the upper side of the idler rolls, shown in FIG. 4A. In some cases it may be desirable for some applications to enable coating (or etching) both side of the substrate (e.g., such as with an anti-static coating, cleaning, etc.). Accordingly, embodiments of method/systems of the preset disclosure invention can provide that the substrate path and transport layout are designed/configured to allow and/or optimize exposure of the back side of the substrate.

Embodiments/features of the present disclosure can prevent (or facilitate prevention/mitigation of) any coating or etching of the back substrate surface by providing a means to collect excess (“overcoat”) material from the source, e.g., as shown in FIGS. 4B and 7. In prior art techniques, it can be undesired characteristic of vacuum coating sources, including e-beam and thermal evaporators, etc., that excess material form the source can be deposited in areas other than the substrate, and this not only requires periodic cleaning, but can interfere with the coating operation when such unwanted deposition occurs on rollers or guides and thereby changes these surfaces and alters the performance of these devices. Also, excess material can contaminate other coatings, either by flaking off of surfaces where a substantial buildup of material exists, or by re-evaporating from heated surfaces.

FIG. 7 depicts a further embodiment 66 (in a side view) similar to the embodiment of FIGS. 4 and 6, in which the tape substrate 73 is unwound from supply spool 70 and traverses coating zone 75 with the same spiral path as previously described, rewinding onto take-up spool 71. This embodiment illustrates collector device 72 for collecting excess material that would otherwise pass through the space between successive wraps of tape and could potentially contaminate other parts of the coater, as well as the back side of the tape. The collector can consist of an unwind/rewind pair of rollers (78/79) with standard web handling rollers for substrate 72, or an endless belt of film running between rollers 78/79. The substrate 72, which could be a plastic film such as PET or other, accumulates excess material during the tape coating operation and is readily discarded as the material buildup necessitates.

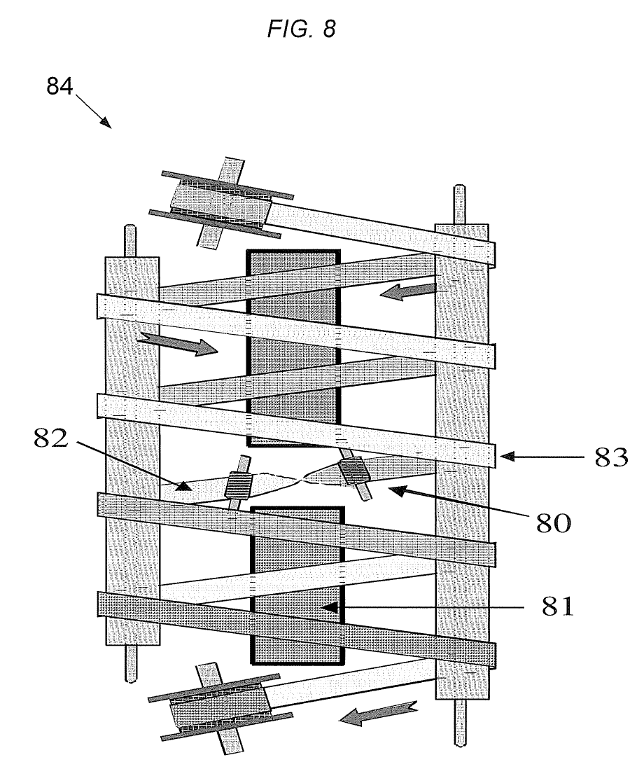

Yet another embodiment, shown as 84 in FIG. 8, includes a method/system by which both sides of the substrate can be coated in a single pass. Here the web path passes over deposition zone 84, coating one side of the substrate, as shown in FIG. 4A, then between feed roller 80 and receiving roller 82 tape 83 is twisted by 180 degrees about the tape axis along the machine direction. The web path continues into subsequent deposition zone 81, where the backside coating is applied.

With continued reference to FIG. 8, the embodiment(s) depicted can accordingly enable dual-side coating, which can be beneficial for substrates requiring both sides to have deposited, such as dual-sided recordable storage media, or substrates requiring a vacuum-deposited backcoat for friction and/or static control. For example, a metallized layer on the back side can act as an effective antistatic coating. Currently, conventional coating methods require either an additional coating pass or an additional backside coating station, both of which add production time and cost.

Accordingly, while certain embodiments have been described herein, it will be understood by one skilled in the art that the methods, systems, and apparatus of the present disclosure may be embodied in other specific forms without departing from the spirit thereof. The present embodiments are therefore to be considered in all respects as illustrative and not restrictive.

What is claimed is:

1. A roll-to-roll system for providing uniformity of vacuum coated flexible substrates, the system comprising:
a. a vacuum system having a source from which a flux of material can be emitted through an area;
b. a means for continuous transport of a substrate through the area of the flux of material; and
c. a substrate path that includes multiple sequential transits through successive areas of the flux of material emitted from the source.

2. The system of claim 1, wherein the path is essentially spiral.

3. The system of claim 1, wherein the length of the material source is greater than the width of the substrate.

4. The system of claim 1, wherein in which the material source is thermal, electron beam, sputter, chemical vapor deposition, polymer multilayer, or any combination thereof.

5. The system of claim 1, wherein the material source comprises multiple material sources.

6. The system of claim 1, wherein material from the source is deposited on a front and back side of the substrate.

7. The system of claim 1, further comprising a shielding means to prevent material deposition on a back side of the substrate.

8. The system of claim 7, wherein the shielding means is static.

9. The system of claim 7, wherein the shielding means is moveable, such as by continuous belt or unwind-to-rewind roll.

10. The system of claim 1, further comprising shutters configured and arranged to improve the uniformity of the source.

11. The system of claim 1, wherein one or more sensors are used to measure the material deposited on the substrate, including reflectometers, fiber-optic sensors, cameras, relay mirrors, laser beams, linear solid-state detectors, etc.

12. The system of claim 11, wherein the measuring sensors are located outside of the deposition area.

13. The system of claim 1, further comprising backing and/or transport and/or guiding rolls that are configured and arranged to support the substrate.

14. The system of claim 13, wherein the guiding rolls comprise cooling rolls, concave side faced rollers, and crowned rollers, or any combination thereof.

15. The system of claim 1, wherein the backing and/or transport rolls and/or guiding rolls support single or multiple widths of substrate.

16. The system of claim 1, wherein the substrate is twisted by 180 degrees to expose the opposite side to the material deposition source.

17. The system of claim 1, wherein multiple deposition zones are used to deposit different materials on each side of the substrate.

18. A roll-to-roll system for improving the uniformity of vacuum etched flexible substrates, the method comprising:
a. a vacuum system having a zone in which material is removed from the substrate;
b. a means for continuous transport of a substrate; and
c. a substrate path includes multiple sequential transits through successive areas of the material removal zone.

19. The system of claim 18, wherein the path is essentially spiral.

20. The system of claim 18, wherein the length of the material source is greater than the width of the substrate.

21. The system of claim 18, wherein the material removal source is RF plasma, inductively coupled plasma, ablation, laser ablation, etc., or any combination thereof.

22. The system of claim 18, wherein material is removed from the front and back side of the substrate.

23. The system of claim 18, wherein one or more sensors are used to measure the material remaining on the substrate, the sensors selected from the group consisting of reflectometers, fiber-optic sensors, cameras, relay mirrors, laser beams, and linear solid-state detectors.

24. The system of claim 18, wherein multiple zones include those for both deposition and removal.

25. The system of claim 24, further comprising a first etching zone configured and arranged to remove residual polymer scum material from substrates with polymeric lithographic masks, followed by deposition of another material or materials, and any sequence of said processes.

26. A roll-to-roll method for improving the uniformity of vacuum etched flexible substrates, the method comprising:
a. providing a vacuum system having a material removal zone in which material can be removed from the substrate;
b. continuously transporting a substrate through the material removal zone; and
c. providing a substrate path for the substrate that includes multiple sequential transits through successive areas of the material removal zone.

27. The method of claim 26, wherein the path is substantially spiral.

28. The method of claim 26, wherein the length of the material source is greater than the width of the substrate.

29. The method of claim 26, wherein the material removal source is RF plasma, inductively coupled plasma, ablation, laser ablation, or any combination thereof.

30. The method of claim 26, wherein material is removed from the front and back side of the substrate.

31. The method of claim 26, further comprising using one or more sensors to measure the material remaining on the substrate.

32. The method of claim 31, comprising using a reflectometer, a fiber-optic sensor, a cameras, a relay mirror, a laser beam, or a linear solid-state detector.

33. The method of claim 26, wherein multiple zones include those for both deposition and removal.

34. The method of claim 33, wherein a first etching zone is used to remove residual polymer scum material from substrates with polymeric lithographic masks, followed by deposition of another material or materials, and any sequence of said processes.
